(19) United States
(12) Patent Application Publication
(10) Pub. No.: US 2005/0151558 A1
(43) Pub. Date: Jul. 14, 2005

(54) Method for inspecting defects on a display panel

(76) Inventor: Hsin-Tao Huang, Shin-Ju City (TW)

Correspondence Address: NATH & ASSOCIATES, 1030 15th STREET, NW, 6TH FLOOR, WASHINGTON, DC, 20005, US

(21) Appl. No.: 10/798,322

(22) Filed: Mar. 12, 2004

(30) Foreign Application Priority Data
Jan. 12, 2004 (TW) 093100728

(51) Int. Cl. G02F 1/13; G01R 31/00

(52) U.S. Cl. 324/770; 349/187

(57) ABSTRACT

Two different curable compounds are mixed to form a conductive adhesive polymer such that display panel and chip can be fastened temporally first for inspecting defects. If defects are found, semi-product can be repaired or rework easily. If there is no defect, the display panel and chip can be securely fastened subsequently.

### BACKGROUND OF THE INVENTION

1. Field of the Invention

The present invention generally relates to a method for inspecting display panel, and more particularly to a method for inspecting defects on an LCD display panel by using a conductive adhesive polymer with two different curable compounds.

2. Description of the Prior Art

In TFT-LCD technical field, bonding LCD panel and driver IC devices needs ACF (Anisotropic Conductive Film) and ACA (Anisotropic Conductive Adhesive) to make electrodes of the LCD panel and the driver IC devices fasten and connect electrically. Traditional material of the ACF comprises polymer base material adhesive and conductive grains uniformly dispensed to the adhesive. The ACF and ACA are widely used in bonding techniques, such as TAB (Tape Automated Bonding), COF (Chip on Film), COG (Chip on Glass), OLB (Outer Lead Bonding), between TFT-LCD glass panel and driver IC devices due to their electrical conductivity.

The traditional material of ACF or ACA selects thermosetting polymer as base agent to reach high sticky or adhesive quality for severe reliability. For example, the material can be chosen from poly ester, epoxy, silicone, and urethane ester, and under high temperature and pressure conditions it will condense or proceed crosslinkage to generate stereo or 3D network structure. The result structure will have resistance to erosion, moisture attacking, and stress tensor. Nevertheless, the result structure will not react with any solvent or reactant due to its stereo network and crosslinkage structure, and hence rework or repair step is not easy to perform between TFT-LCD glass panel and driver IC devices in bonding process. More particularly, in the COG process, because the driver IC devices are bare chips and bonding to glass substrate directly, the bare chips are therefore easily broken on the glass substrate, or some pieces of ACF remain on the glass substrate and can't be removed efficiently. The glass substrate is then scrapped. The larger size of the glass substrate is, the greater damage happens in rework or repair.

Detail processes of bonding LCD panel and driver IC chips by using traditional thermosetting ACF and inspecting the LCD display panel can be illustrated in FIG. 1. First, the ACF is applied or stuck to electrodes of an LCD panel or driver IC devices 100. Then, a heating step 101 is performed such that thermosetting material in the ACF is cured to securely fasten the LCD panel and the driver IC devices. A UV (ultra violet) sealant is coated 102 on the LCD panel and exposed to UV radiation to cure the UV sealant 103. An inspecting step is then performed 104 to check whether the LCD panel has any defect. If there is no defect on the panel, it will be sent to next process 106. However, if there is any defect on the panel, it will be discarded 105.

In order to repair or rework, another thermoplastic polymer can be selected as base agent to achieve temporal fastening the panel and the driver IC devices. A possible material can be resin formed from poly ethylene, polyvinyl chloride, methyl methylacrylate, and polyimide, which shows plasticity in high temperature. When these kind of materials are applied to the bonding process, rework or repair process, hence, can be performed at high temperature to remove driver IC devices and ACF completely after any defect of misalignment or mismatch is found. Discarding the expensive glass panel then can be avoided. However, such a high temperature may cause damage or have reliability issue to the LCD panel on the foregoing high temperature process or application environment.

In order to repair or rework as well as to satisfy reliability under next high temperature process or application environment, different mixing proportions of thermosetting polymer and thermoplastic material as adhesive are used, which can be shown in Technical Report CP7652 on Applying ACF to COG by Sony, UV Curable Coatings for Electronic Devices (IEEE treatment to device package and manufacturing technology, part A, vol. 17 No. 3, 1994 Sept), Engineering Theory of Polymer (Bri. Oxford, Oxford Press, 1987), and Foundation Theory of Polymer Materials (New York, Wiley and Sons press, 1982). However, the adhesive mixed with thermosetting and thermoplastic polymer can not achieve reliability and rework/repair objective mentioned above in practice use.

### SUMMARY OF THE INVENTION

For the invention background mention above, the traditional inspecting defects method that create many problems. One purpose of this invention is that two fastening steps are performed such that repair or rework process can be proceeded much more easily after the inspecting step. The two fastening steps have two different curing methods, which one is by heating and another is by exposing.

It is another object of this invention that a new conductive adhesive polymer is used so as to fasten objects by two different kinds of curing methods.

It is a further object of this invention that deficient panel does not need to be discarded after defect is inspected.

It is a still further object of this invention to promote product yield by convenient repair or rework process if defect is found.

According to the objects above, this invention provides a method for inspecting a display panel. First, the display panel and chip is fastened temporally, and then inspected for defects. If there is no defect, the display panel and chip are then fastened securely. The display panel in this invention can be LCD panel.

The temporally fastening step can be performed by heating a conductive adhesive polymer between the display panel and a chip, wherein the conductive adhesive polymer comprises a thermosetting resin, a photo-curable polymer, and conductive grains. The securely fastening step can be performed by lighting the conductive adhesive polymer between the display panel and the chip.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 illustrates a flow chart of bonding an LCD panel to driver IC devices by using traditional method;

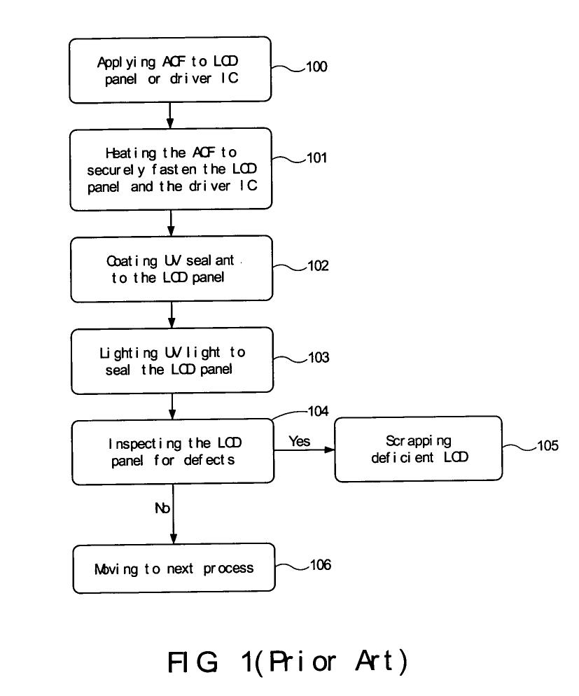

FIG. 2 illustrates a flow chart of inspecting defects with two different fastening steps so as to repair or rework deficient display panel easily in accordance with this invention; and

FIG. 3 illustrates a flow chart that an LCD panel and driver IC devices are fastened by using conductive adhesive polymer in accordance with this invention.

### DESCRIPTION OF THE PREFERRED EMBODIMENT

Some sample embodiments of the present invention will now be described in greater detail. Nevertheless, it should be recognized that the present invention can be practiced in a wide range of other embodiments besides those explicitly described, and the scope of the present invention is expressly not limited except as specified in the accompanying claims.

This invention provides a method for inspecting defects on a display panel that includes steps of temporally fastening the display panel and a driver IC device, inspecting the display panel for defects, and fastening the display panel and the driver IC chip securely. The display panel can be repaired or rework if defects are found at the inspecting step. The display panel in this invention can be LCD panel or PDP panel.

The temporally fastening step can be performed by heating a conductive adhesive polymer between the display panel and a chip, wherein the conductive adhesive polymer comprises a thermosetting resin, a photo-curable polymer, a photo-initiator, and conductive grains. The securely fastening step can be performed by lighting the conductive adhesive polymer between the display panel and the chip. Proportion of the thermosetting resin and the photo-curable polymer can be ranged from 50:50 to 90:10, and proportion of the photo-initiator can be ranged from 0.1 to 5 weight percentage and the conductive grains, which can be conductive micro particles or plastic micro particles deposited with metal, are dispensed on the adhesive uniformly.

The thermosetting resin can be polyester, epoxy compound, silicone, and urethane ester. The photo-curable polymer can be UV (ultraviolet) curable polymer, EB (electron beam) curable polymer, IR (infrared) curable polymer, or VL (visual light) curable polymer. The Ultra-violet photo-curable polymer can be epoxy resin, biphenol resin, unsaturated polyester, or acrylate resin which can be urethane diacrylate or epoxy diacrylate. The light initiator can be Benzoin monomethyl ether, Benzoin methyl ether, or bezonphenone, which will be decided by different wave lengths lights.

The VL curable polymer can be un-aromatic amine, which can be mixture of methyl acrylic acid N, N-dimethylamino ethyl ester and ketone or diketone which can absorb visual light from 400-500 nm wave lengths.

The thermosetting resin used in the conductive adhesive in this invention provides sticky level sufficient to temporally fasten the driver IC devices and the LCD panel for following inspecting process, and proportion between the thermosetting resin and the photo-curable polymer can be ranged from 50 to 90 weight percentage. Base on the requirement of the rework or repair, preferred proportion of the photo-curable polymer can be 10 to 90 weight percentage. The more photo-curable polymer is the better for panel rework or repair is. The inspecting process checks electrodes misalignment between the glass panel and the driver IC devices, unbonded COG, failure glass panel or driver IC devices.

Assembly of the glass panel and the driver IC devices temporally fastened by heating the conductive adhesive is also called semi-manufacture in this invention of inspecting method.

After inspecting the display panel for defects, the display panel and the chip are sealed by using photo-curable sealant. The seal process includes applying or coating the photo-curable sealant to the display, and then lighting to cure the photo-curable sealant. The photo-curable sealant can be UV photo-curable sealant, EB photo-curable sealant, IR photo-curable sealant, and VL photo-curable sealant. A preferred material is same with photo-curable polymer in the conductive adhesive polymer, such that the sealing process and the securely fastening step can be merged together or performed in one step. The ultra-violet photo-curable sealant can be epoxy resin, biphenol resin, unsaturated polyester, or acrylate resin.

The inspecting method includes at least two processes, one optical instrument checking and another electrical characteristic checking. The optical instrument checking inspects bonding and alignment between the LCD panel and the driver devices, while the electrical characteristic checking inspects assembly of the LCD panel and the driver devices for defects by a testing screen sent from a test controlling system.

The term “defects” means that any panel or LCD panel can't pass through the inspecting method, including the optical instrument checking and the electrical characteristic checking. The defects includes misalignment between the LCD panel and the driver IC devices, failure bonded devices, failure in electric connection, intrinsic drawbacks in driver IC devices manufacture, or LCD device can't be drove.

For example, when misalignment or failure bonding is found by optical instrument checking, driver IC devices may be removed from the panel and another inspecting step is performed to see if the panel and the driver IC devices can be available. If it is, the present invention can be applied again to use the conductive adhesive polymer to fasten the LCD panel and the driver IC devices.

When electrical characteristic checking is performed, a testing screen is sent from a testing controlling system to see if there is any intrinsic defect about panel or driver IC per se. If it is, the panel or driver IC will be examined to see if it can be repaired. If it can be repaired, a laser repair process will be performed and sent to next process. On the other hand, if it can't be repaired, the driver IC devices are removed from the panel and check if there is any device available.

The optical instrument and the electrical characteristic checking in this invention can be any checking that persons ordinary skilled in the art are familiar with.

The conductive adhesive compound in this invention can be formed in liquid state and injected to the panel or driver device. Alternatively, it can also be made as dry film that used like a tape.

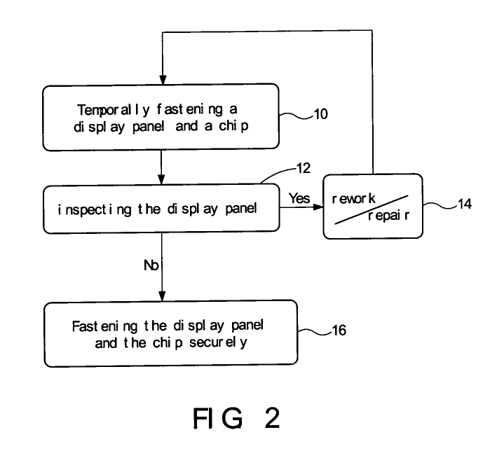

A flow chart illustrating this inspecting method is shown in FIG. 2. First, a display panel, which can be LCD panel or other panel such as PDP panel, and at least one chip are temporally fastened 10, wherein the chip is usually driver IC device. This temporally fastening step can be performed by using mixed adhesive polymer including thermosetting resin and photo-curable polymer, when the thermosetting resin is heated. Then, the display panel can be inspected for defects 12. If there is any defect found in the panel or driver IC device, rework or repair process 14 can be proceeded easily for the panel and chip are just fastened temporally. A securely fastening step 16 is proceeded if there is no defect found in either panel or driver IC device, when the photo-curable polymer in the mixed adhesive polymer is exposed to a corresponding wavelength light thereof.

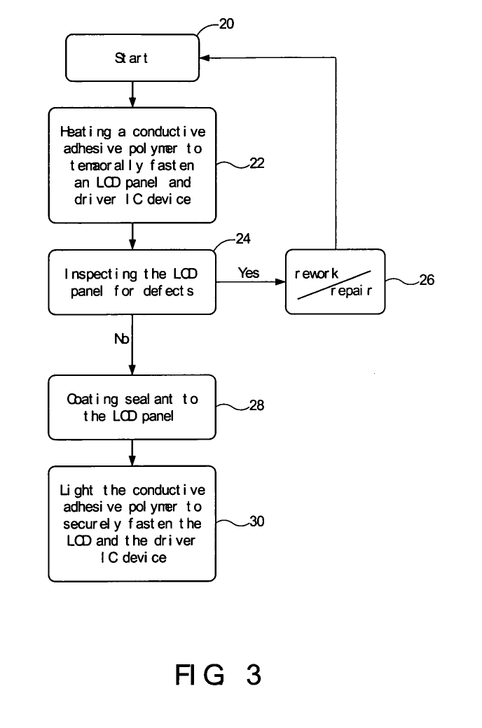

Another flow chart showing this inspecting method can be referred to FIG. 3. When this inspecting step start 20, a conductive adhesive polymer is applied to a display panel or driver IC devices, wherein the conductive adhesive polymer can be mixture compound including at least a thermosetting resin, a photo-curable polymer, and conductive grains. The conductive grains are dispensed and distributed uniformly in the conductive adhesive polymer. Moreover, a photo-initiator can be applied to the conductive adhesive polymer as a trigger when the conductive adhesive polymer is exposed to the corresponding wavelength light.

Then, the conductive adhesive polymer is heated 22 to temporally fasten the display panel and the driver IC devices for the heated thermosetting resin will be cured. This panel can be inspected for defects 24 now. If there is any defect found in the panel or driver IC device, it can be sent to rework or repair 26 immediately for the panel and the driver IC device are just fasten temporally and can be remover easily compared to the prior art. Such a rework or repair process needs another inspecting step to determine if repair process can be proceeded first. If the panel can't be repaired, still another inspecting step should be performed to determine whether the panel can be rework. After the panel is repaired or reworked, it will be sent to the start status to proceed the inspecting defects method again.

If there is no defect found in the panel or driver IC device, the panel should be sealed by applying sealant thereto 28. The sealant is photo-curable that can be cured by exposing to light. When a corresponding wave length light is illuminated, the sealant is cured. The photo-curable sealant can have primary the same ingredients compared to the photo-curable polymer. Therefore, the lighting or illuminating step can be omitted and merged to the next fastening step.

Then, the conductive adhesive polymer in the panel is exposed to corresponding wavelength light to securely fasten the driver IC device 30. If sealant is chosen the same ingredient with the photo-curable polymer, the sealing process can be finished simultaneously. After the panel is inspected and fastened with the driver IC chip, it will be sent to the next process.

The main advantage of this invention is that two fastening steps are performed such that repair or rework process can be proceeded much more easily after the inspecting step. The two fastening steps have two different curing methods, which one is by heating and another is by exposing. A new conductive adhesive polymer is used in this invention so as to fasten objects by two different kinds of curing methods. Deficient panels do not need to be discarded after defect is inspected. Moreover, this invention promotes product yield by convenient repair or rework process if defect is found.

Although specific embodiments have been illustrated and described, it will be obvious to those skilled in the art that various modifications may be made without departing from what is intended to be limited solely by the appended claims.

1. A method for inspecting a liquid crystal display panel, comprising steps of:
temporally fastening the liquid crystal display panel and a driver IC device;
inspecting the liquid crystal display panel for defects; and
fastening the liquid crystal display panel and the driver IC chip securely.

2. The method according to claim 1, further comprising a step of repairing the liquid crystal display panel if the defects are found at said step of inspecting.

3. A method for inspecting a display panel, comprising steps of:
heating a conductive adhesive polymer to temporally fasten the display panel and a chip, wherein said conductive adhesive polymer comprises a thermosetting resin, a photo-curable polymer, a photo-initiator, and conductive grains; and
inspecting the display panel for defects.

4. The method according to claim 3, further comprising a step of inspecting the defects for repairing if the display panel has the defects.

5. The method according to claim 4, further comprising a step of sealing the display panel and the chip.

6. The method according to claim 5, further comprising a step of lighting said conductive adhesive polymer to securely fasten the display panel and the chip.

7. The method according to claim 3, further comprising a step of applying a photo-curable sealant to the display panel and the chip.

8. The method according to claim 7, wherein said photo-curable sealant is selected from the group consisting of ultraviolet photo-curable sealant, electron beam photo-curable sealant, infrared photo-curable sealant, and visual light photo-curable sealant.

9. The method according to claim 8, wherein said ultra-violet photo-curable sealant is selected from the group consisting of epoxy resin, biphenol resin, unsaturated polyester, and acrylate resin.

10. The method according to claim 9, further comprising a step of lighting to cure the photo-curable sealant.

11. The method according to claim 7, further comprising a step of lighting said conductive adhesive polymer to securely fasten the display panel and the chip.

12. The method according to claim 3, wherein said inspecting step comprises an optical inspecting step.

13. The method according to claim 12, wherein said inspecting step comprises an electrical inspecting step.

14. The method according to claim 3, wherein proportion of said thermosetting resin and said photo-curable polymer is ranged from 50:50 to 90:10.

15. The method according to claim 14, wherein proportion of said photo-initiator is ranged from 0.1 to 5 weight percentage.

16. The method according to claim 3, wherein said thermosetting resin is selected from the group consisting of polyester, epoxy compound, silicone, and urethane ester.

17. The method according to claim 16, wherein said photo-curable polymer is selected from the group consisting of ultraviolet photo-curable polymer, electron beam photo-curable polymer, infrared photo-curable polymer, and visual light photo-curable polymer.

18. The method according to claim 17, wherein said Ultra-violet photo-curable polymer is selected from the group consisting of epoxy resin, biphenol resin, unsaturated polyester, and acrylate resin.

19. A method for inspecting a liquid crystal display panel for defects, comprising steps of:
temporally fastening the liquid crystal display panel and a chip by heating a conductive adhesive therebetween, wherein said conductive adhesive comprises a thermosetting resin, a photo-curable polymer, a photo-initiator, and conductive grains;
inspecting the liquid crystal display panel for defects;
sealing the liquid crystal display panel and the chip; and
fastening the liquid crystal display panel and the chip securely by lighting said conductive adhesive.
